(19) United States
(12) Patent Application Publication
(10) Pub. No.: US 2013/0089961 A1
(43) Pub. Date: Apr. 11, 2013

(54) Methods of Forming Semiconductor Devices Including an Epitaxial Layer and Semiconductor Devices Formed Thereby

(71) Applicants: Geo Myung SHIN, Seoul (KR); Myungsun KIM, Hwaseong-si (KR); Dongsuk SHIN, Yongin-si (KR); Naein LEE, Seoul (KR)

(72) Inventors: Geo Myung SHIN, Seoul (KR); Myungsun KIM, Hwaseong-si (KR); Dongsuk SHIN, Yongin-si (KR); Naein LEE, Seoul (KR)

(73) Assignee: Samsung Electronics Co., Ltd.

(21) Appl. No.: 13/615,990

(22) Filed: Sep. 14, 2012

(30) Foreign Application Priority Data
Oct. 6, 2011 (KR) 10-2011-0102010

(51) Int. Cl. H01L 21/336

(52) U.S. Cl. 438/294; 257/E21.409

(57) ABSTRACT

Methods of forming a semiconductor device are provided. The methods may include forming an epitaxial layer by growing a crystalline layer using a semiconductor source gas in a reaction chamber, and by etching the crystalline layer using an etching gas in the reaction chamber.

### CROSS-REFERENCE TO RELATED APPLICATIONS

This U.S. non-provisional patent application claims priority under 35 U.S.C. §119 to Korean Patent Application No. 10-2011-0102010, filed on Oct. 6, 2011, in the Korean Intellectual Property Office, the disclosure of which is hereby incorporated by reference in its entirety.

### BACKGROUND

The present disclosure relates to methods of forming semiconductor devices and semiconductor devices formed thereby.

To meet a growing demand for lightweight, small-sized, high-speed, multifunctional, high-performance, high-reliability, and low-cost electronic devices, the integration density of semiconductor memory devices has increased. The increased integration density of semiconductor devices, however, may lead to a decrease in line width of gate electrodes, which may further lead to a decrease in transistor channel length, an increase in short channel effect, and deterioration in characteristics of the semiconductor devices.

### SUMMARY

A method of forming a semiconductor device according to various embodiments may include forming a device isolation pattern in a substrate to define an active region. The method may further include forming an epitaxial layer on the active region. The method may also include forming a gate electrode on the epitaxial layer to cross the active region. Moreover, forming the epitaxial layer may include growing a crystalline layer using a semiconductor source gas in a reaction chamber, performing a first purging of the reaction chamber, etching the crystalline layer using an etching gas in the reaction chamber, and performing a second purging of the reaction chamber.

In various embodiments, a cyclic process, including each of growing the crystalline layer using the semiconductor source gas, performing the first purging, etching the crystalline layer using the etching gas, and performing the second purging, may be performed two or more times during the forming of the epitaxial layer.

According to various embodiments, growing the crystalline layer using the semiconductor source gas may be performed to grow the crystalline layer in vertical and horizontal directions with respect to a top surface of the substrate. Additionally, etching the crystalline layer may be performed to etch the horizontally grown portion of the crystalline layer.

In various embodiments, etching the crystalline layer may be performed using a reaction gas including the etching gas and not including a semiconductor source gas.

According to various embodiments, the etching gas may include halogen elements.

In various embodiments, forming the gate electrode may include forming a dielectric layer, a first conductive layer, and a second conductive layer on the substrate in a sequential manner Forming the gate electrode may also include patterning the dielectric layer, the first conductive layer, and the second conductive layer. Moreover, the first conductive layer may include a conductive metal nitride layer and the dielectric layer may include a high-k dielectric layer.

According to various embodiments, the method may further include forming spacers on the active region to cover opposing sidewalls of the gate electrode. Additionally, forming the spacers may include forming a spacer layer on the substrate and anisotropically etching the spacer layer to expose the epitaxial layer.

In various embodiments, the method may further include etching the epitaxial layer using the gate electrode and the spacers as an etch mask to expose the active region.

According to various embodiments, forming the gate electrode may further include forming a sacrificial metal layer on the substrate. Forming the gate electrode may additionally include performing a thermal treatment process on the substrate to form a first metal-semiconductor compound pattern on the patterned second conductive layer.

In various embodiments, forming the sacrificial metal layer and performing the thermal treatment process may include forming a second metal-semiconductor compound pattern on the active region.

According to various embodiments, forming the device isolation pattern to define the active region may include defining a first active region and a second active region. Also, forming the epitaxial layer may include forming a first epitaxial layer and a second epitaxial layer. The first epitaxial layer may be between the first active region and the gate electrode, and the second epitaxial layer may be between the second active region and the gate electrode. Additionally, a top surface of the first active region may have a greater area than a top surface of the second active region. Furthermore, a growth rate of the first epitaxial layer may be substantially equal to that of the second epitaxial layer.

In various embodiments, forming the epitaxial layer may be performed at a temperature ranging from about 300 degrees Celsius to about 900 degrees Celsius. Additionally, each of etching the crystalline layer using the etching gas and growing crystalline layer using the semiconductor source gas may be performed during a process time ranging from about 5 seconds to about 100 seconds.

A semiconductor device according to various embodiments may include a device isolation pattern defining an active region in a substrate. The semiconductor device may also include a gate electrode on the active region. The semiconductor device may additionally include a pair of doped regions in the active region adjacent opposing sidewalls of the gate electrode. The semiconductor device may further include an epitaxial layer between the active region and the gate electrode. Moreover, the epitaxial layer may include a semiconductor material including an energy band gap that is less than an energy band gap of a semiconductor material in the active region. Additionally, a maximum width in a specific direction of the epitaxial layer may be substantially equivalent to a minimum width in the specific direction of the active region.

In various embodiments, the epitaxial layer may include a portion configured to provide a channel region of a transistor, when a voltage is applied to the doped regions and the gate electrode.

According to various embodiments, the epitaxial layer may include a rounded portion connecting a top surface thereof to a side surface thereof. Also, a tangential plane of the rounded portion may form an angle ranging from about 45 degrees to about 65 degrees, with respect to a top surface of the substrate.

A method of forming a semiconductor device according to various embodiments may include supplying a semiconductor source gas to a substrate in an epitaxy reaction chamber to grow a crystalline structure on the substrate. The method may also include supplying an etching gas in the epitaxy reaction chamber to etch a portion of the crystalline structure. The method may additionally include repeatedly supplying the semiconductor source gas to grow the crystalline structure and supplying the etching gas to etch the crystalline structure to form an epitaxial layer that is on an active region of the substrate and that exposes a recess between the active region of the substrate and an adjacent device isolation pattern. The method may further include forming a dielectric layer on the epitaxial layer. The method may also include forming first and second conductive layers on the dielectric layer. The method may additionally include patterning the dielectric layer and the first and second conductive layers to expose the recess.

In various embodiments, the method may further include purging the epitaxy reaction chamber a first time between supplying the semiconductor source gas to grow the crystalline structure and supplying the etching gas to etch the crystalline structure. The method may also further include purging the epitaxy reaction chamber a second time after supplying the etching gas to etch the crystalline structure.

According to various embodiments, forming the epitaxial layer on the active region of the substrate may include forming first and second active regions on the substrate. Also, forming the epitaxial layer may include forming a first epitaxial layer and a second epitaxial layer. The first epitaxial layer may be between the first active region and the dielectric layer, and the second epitaxial layer may be between the second active region and the dielectric layer. Additionally, a top surface of the first active region may have a greater area than a top surface of the second active region. Furthermore, a thickness of the first epitaxial layer may be substantially equal to a thickness of the second epitaxial layer.

In various embodiments, the method may also include forming spacers on opposing sidewalls of the dielectric layer and on opposing sidewalls of the first and second conductive layers. The method may further include etching the first and second epitaxial layers using the spacers and the second conductive layer as an etch mask.

According to various embodiments, the method may further include forming channel regions in the first and second epitaxial layers. Moreover, each of the first and second epitaxial layers may include a semiconductor material including an energy band gap that is less than an energy band gap of a semiconductor material in the first and second active regions, respectively.

### BRIEF DESCRIPTION OF THE DRAWINGS

The above and other features and advantages of the disclosure will become more apparent in view of the attached drawings and accompanying detailed description.

FIG. 1 is a flow chart illustrating a method of forming an epitaxial layer in a method of fabricating a semiconductor device, according to various embodiments of the inventive concept.

FIGS. 2A through 2F are enlarged views illustrating a method of forming an epitaxial layer in a method of fabricating a semiconductor device, according to various embodiments of the inventive concept.

FIGS. 3A, 4A, 5A, 6A, 7A, and 8A are plan views illustrating a method of fabricating a semiconductor device, according to various embodiments of the inventive concept.

FIGS. 3B, 4B, 5B, 6B, 7B, and 8B are sectional views taken along a line I-I′ of FIGS. 3A, 4A, 5A, 6A, 7A, and 8A, respectively.

FIGS. 5C, 6C, 7C, and 8C are sectional views taken along a line II-II′ of FIGS. 5A, 6A, 7A, and 8A, respectively.

FIG. 9 is a schematic block diagram illustrating an example of memory systems including a semiconductor device, according to various embodiments of the inventive concept.

FIG. 10 is a schematic block diagram illustrating an example of memory cards including a semiconductor device, according to various embodiments of the inventive concept.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the teachings of the present embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

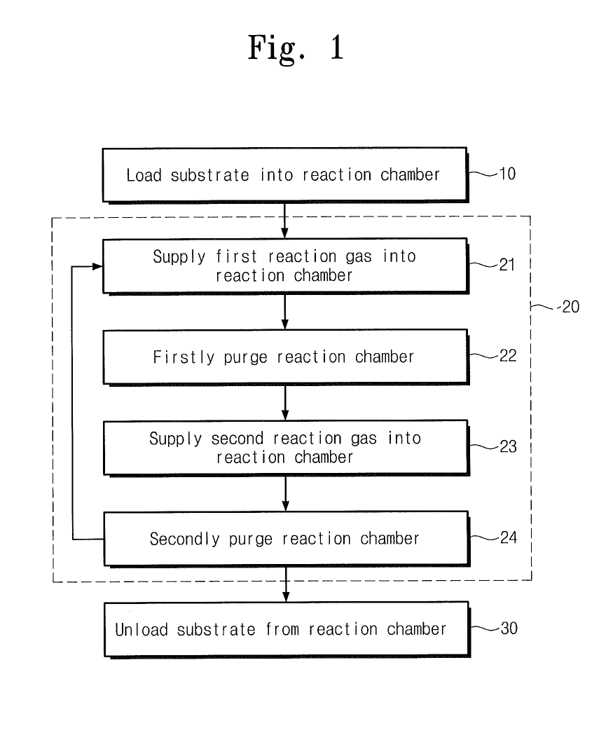

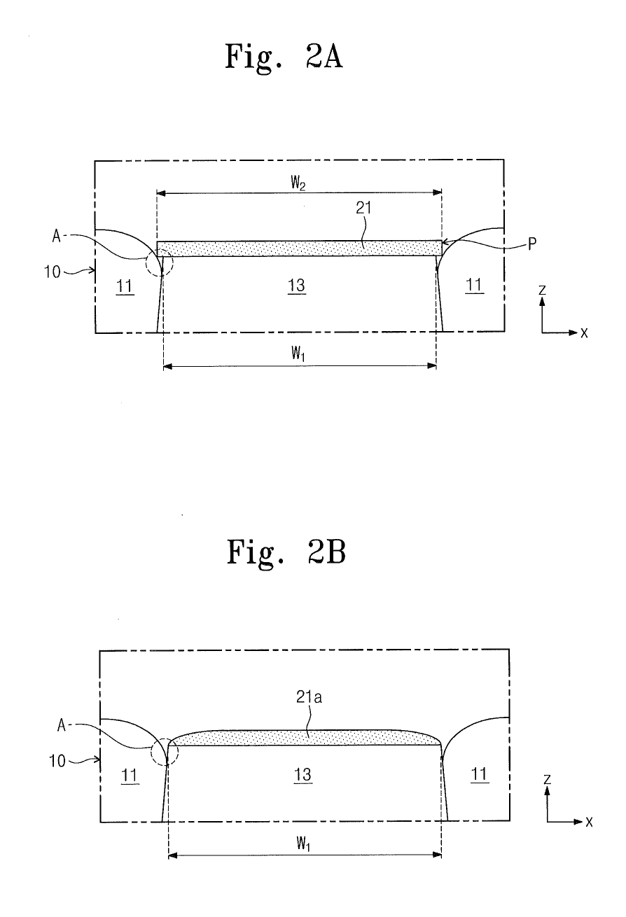

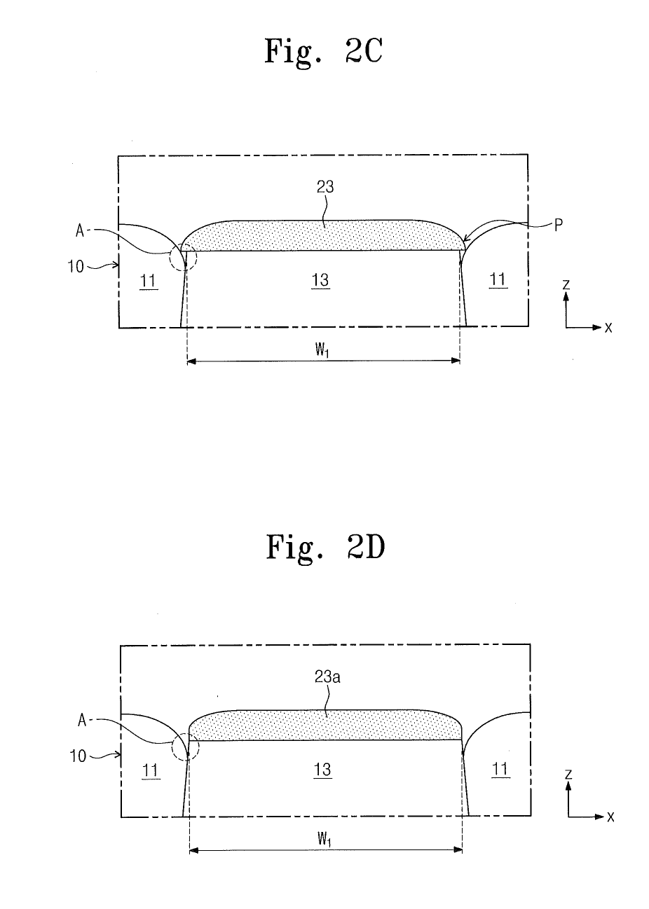

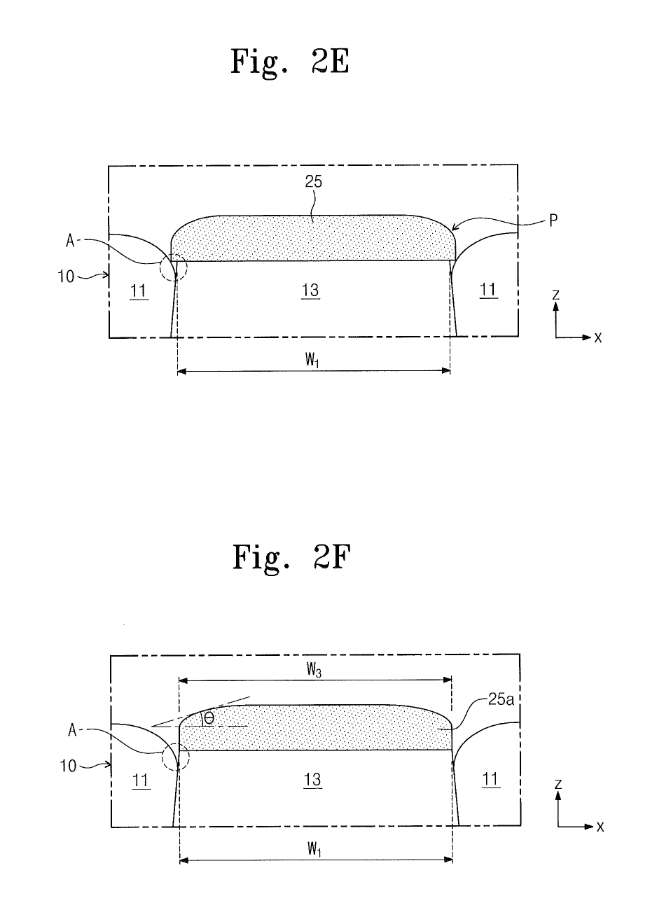

An epitaxial-film-forming method, which may be used as a part of a process of forming/fabricating a semiconductor device according to various embodiments of the inventive concept, is described herein with reference to FIGS. 1 and 2A through 2F. FIG. 1 is a flow chart illustrating a method of forming an epitaxial layer, and FIGS. 2A through 2F are provided to explain exemplarily the epitaxial-film-forming method and are sectional views enlarging portions of an active region and a device isolation pattern.

Referring to FIGS. 1 and 2A, a substrate 10 may be provided to include a device isolation pattern 11 defining an active region 13. The substrate 10 may be loaded in a reaction chamber of an epitaxy apparatus (Block 10). In addition to the reaction chamber, the epitaxy apparatus may further include a load-lock chamber, a transfer chamber, and a transfer robot. The substrate 10 may be delivered to the transfer chamber via the load-lock chamber. The substrate 10 may be loaded in the reaction chamber using the transfer robot provided in the transfer chamber. In various embodiments, the reaction chamber may be of a single wafer processing type.

An epitaxial process (Block 20) may be performed on the loaded substrate 10 at least once to form an epitaxial layer 25a (illustrated in FIG. 2F) on the substrate 10. In various embodiments, the epitaxial process (Block 20) may be performed several times in such a way that the epitaxial layer 25a may have a desired thickness. In various embodiments, the epitaxial process (Block 20) may be performed in the reaction chamber configured to maintain a process temperature of about 300-900 degrees Celsius. The epitaxial process (Block 20) may include injecting a first reaction gas into the reaction chamber (Block 21), firstly purging the reaction chamber (Block 22), injecting a second reaction gas into the reaction chamber (Block 23), and secondly purging the reaction chamber (Block 24).

Referring again to FIGS. 1 and 2A, a first subsidiary layer 21 may be formed on the active region 13, as the result of the injection of the first reaction gas into the reaction chamber (Block 21). The first reaction gas may be provided into the reaction chamber during a process time of about 5-100 seconds.

During the injection of the first reaction gas, semiconductor atoms decomposed from semiconductor source gas may be bonded and adsorbed to dangling bonds on a surface of the active region 13. Accordingly, a crystalline structure may be grown from a surface of the active region 13 to form the first subsidiary layer 21.

In various embodiments, the maximum width W2 in a specific direction of the first subsidiary layer 21 may be greater than the minimum width W1 in the same direction of a top surface of the active region 13. The specific direction may be parallel to an x-axis (e.g., the x-axis illustrated in FIG. 2A). The crystalline structure may be mainly grown in directions perpendicular or parallel to an exposed surface of the substrate 10. Accordingly, the first subsidiary layer 21 may be formed to have a protruding portion P extending from the active region 13 toward the device isolation pattern 11. Furthermore, a recess region A may be formed at a boundary region between the active region 13 and the device isolation pattern 11. The protruding portion P of the first subsidiary layer 21 may partially shield an upper portion of the recess region A.

In various embodiments, top and side surfaces of the first subsidiary layer 21 may have different lattice planes from each other. For example, the top surface of the first subsidiary layer 21 may have a lattice plane of (001), whereas a side surface of the first subsidiary layer 21 may have a lattice plane of (110).

The first reaction gas may include a semiconductor source gas. In various embodiments, the semiconductor source gas may be a silicon source gas and/or a germanium source gas. For example, the silicon source gas may include at least one of silane (SiH₄), disilane (Si₂H₆), dichlorosilane (SiH₂Cl₂), trichlorosilane (SiHCl₃), and/or silicon tetrachloride (SiCl₄), and the germanium source gas may include germanium tetrahydride (GeH₄).

In various embodiments, the first reaction gas may further include a carbon source gas. For example, the carbon source gas may include ethane (C₂H₆) or methylsilane (CH₃SiH₃). In a case in which the first reaction gas includes the carbon source gas, the first subsidiary layer 21 may include a carbon-semiconductor compound.

In various embodiments, the first reaction gas may further include an etching gas. The etching gas may be a gas containing halogen elements. For example, the etching gas may be a hydrogen chloride (HCl) gas, a chlorine (Cl₂) gas, and/or a sulfur hexafluoride (SF₆) gas.

Semiconductor atoms decomposed from the semiconductor source gas of the first reaction gas may be bonded to dangling bonds on the surfaces of the device isolation pattern 11 as well as the active region 13 and adsorbed thereto. Because the device isolation pattern 11 includes a dielectric material, bonding energy of semiconductor atoms may be smaller on the surface of the device isolation pattern 11 than on the surface of the active region 13. Accordingly, semiconductor atoms bonded to the surface of the device isolation pattern 11 may be easily reacted with the etching gas in the first reaction gas to form a semiconductor-halogen compound (for example, silicon tetrachloride (SiCl4)), which may be a gaseous by-product. As a result, semiconductor atoms bonded to the surface of the device isolation pattern 11 can be relatively easily removed from the surface of the device isolation pattern 11, and the first subsidiary layer 21 can be selectively grown from the surface of the active region 13.

In various embodiments, the first reaction gas may further include a doping gas. For example, the doping gas may include at least one gas of phosphine (PH₃), diborane (B₂H₆), or arsine (AsH₃). In a case in which the first reaction gas includes the doping gas, the first subsidiary layer 21 may be formed of a doped semiconductor layer.

Thereafter, the first purging of the reaction chamber (Block 22) may be performed. The first purging (Block 22) may be performed to evacuate the gas and/or by-products of the reaction from the reaction chamber. In various embodiments, the first purging (Block 22) may include supplying a hydrogen gas into the reaction chamber. As a result of supplying the hydrogen gas, the reaction gas and/or the reaction by-products remaining in the reaction chamber (for example, silicon tetrachloride (SiCl₄)) can be evacuated from the reaction chamber. Furthermore, the hydrogen gas may help to remove a natural oxide layer and pollutants from the surface of the first subsidiary layer 21.

Referring to FIGS. 1 and 2B, a second reaction gas may be injected into the reaction chamber (Block 23). The second reaction gas may include an etching gas. In various embodiments, unlike the first reaction gas, the second reaction gas may not include the semiconductor source gas. The etching gas included in the second reaction gas may be a gas including halogen elements. For example, the etching gas may be a hydrogen chloride (HCl) gas, a chlorine (Cl2) gas, and/or a sulfur hexafluoride (SF6) gas.

Because the second reaction gas does not include the semiconductor source gas, growth of the crystalline structure may be halted during the second injection of the reaction gas (Block 23). In addition, because the second reaction gas includes the etching gas, a portion of the first subsidiary layer 21 may be etched by the etching gas. In a case in which a side surface and the top surface of the first subsidiary layer 21 have lattice planes different from each other, the side and top surfaces of the first subsidiary layer 21 may be etched at different etch rates from each other. For example, the etch rate of the first subsidiary layer 21 may be greater at the side surface than the top surface thereof.

Side and edge portions of the first subsidiary layer 21 may be etched by the etching gas. The side portion of the first subsidiary layer 21 may be the protruding portion P extending from the active region 13 toward the device isolation pattern 11. The edge portion of the first subsidiary layer 21 may be a portion interposed between the side portion and the top surface of the first subsidiary layer 21. The recess region A formed between the active region 13 and the device isolation pattern 11 may be exposed, as a result of the etching of the side and edge portions of the first subsidiary layer 21. In the specific direction (e.g., a direction substantially parallel to the x-axis illustrated in FIGS. 2A and 2B), the maximum width of the etched structure of the first subsidiary layer 21 (or an etched first subsidiary layer 21a) may be substantially equivalent to the minimum width W1 of the top surface of the active region 13.

Referring again to the epitaxial process (Block 20) illustrated in FIG. 1, a second purging of the reaction chamber (Block 24) may be performed. The second purging (Block 24) may be performed to evacuate the second reaction gas and/or by-products of the reaction from the reaction chamber. In various embodiments, the second purging (Block 24) may include supplying a hydrogen gas into the reaction chamber. As a result of supplying the hydrogen gas, the second reaction gas and/or the reaction by-products remaining in the reaction chamber can be evacuated from the reaction chamber. Furthermore, the hydrogen gas may help to remove a natural oxide layer and pollutants from the surface of the etched first subsidiary layer 21a.

In various embodiments, the epitaxial process (Block 20) may be again performed on the substrate 10 provided with the etched first subsidiary layer 21a.

Referring to FIGS. 1 and 2C, as a result of re-supplying the first reaction gas into the reaction chamber (e.g., repeating Block 21), a crystalline structure may be grown from the etched first subsidiary layer 21a on the active region 13 to form a second subsidiary layer 23. The first reaction gas may be supplied into the reaction chamber during a process time of about 5-100 seconds, as described with reference to FIG. 2A.

During the re-supplying the first reaction gas, semiconductor atoms decomposed from the semiconductor source gas may be bonded and adsorbed to a surface of the etched first subsidiary layer 21a. In various embodiments, the re-supplying the first reaction gas may result in growth of a crystalline structure from the etched first subsidiary layer 21a, which may occur mainly in directions perpendicular or parallel to the top surface of the substrate 10. Accordingly, the maximum width of the second subsidiary layer 23 in the specific direction (e.g., a direction substantially parallel to the x-axis illustrated in FIGS. 2A-2C) may be greater than the minimum width W1 of the active region 13.

Because the maximum width in the specific direction of the second subsidiary layer 23 is greater than the minimum width W1 in the same direction of the active region 13, the second subsidiary layer 23 may cover at least portion of the recess region A, which may be formed near an interface between the active region 13 and the device isolation pattern 11.

In various embodiments, the first purging (Block 22) may be again performed (e.g., may be repeated) to purge the reaction chamber.

Referring to FIGS. 1 and 2D, the second reaction gas may be re-supplied into the reaction chamber (Block 23). Due to the presence of the etching gas in the second reaction gas (e.g., due to repeating Block 23), a side portion of the second subsidiary layer 23 may be etched. The side portion of the second subsidiary layer 23 to be etched may be a portion P protruding from the active region 13 toward the device isolation pattern 11. As a result of the etching process, the recess region A may be exposed near the interface between the active region 13 and the device isolation pattern 11. In various embodiments, the maximum width in the specific direction of the etched second subsidiary layer 23a may be substantially equal to the minimum width W1 in the same direction of the top surface of the active region 13.

In various embodiments, the second purging (Block 24) may be again performed (e.g., may be repeated) to purge the reaction chamber.

According to various embodiments of the inventive concept, to form the epitaxial layer 25a with a desired thickness, the epitaxial process (Block 20) may be repeatedly performed on the substrate 10 provided with the etched second subsidiary layer 23a.

Referring to FIGS. 1 and 2E, as a result of re-supplying the first reaction gas into the reaction chamber (e.g., as a result of repeating Block 21), a crystalline structure may be grown on/from the etched second subsidiary layer 23a on the active region 13 to form a preliminary epitaxial layer 25. The first reaction gas may be supplied into the reaction chamber during a process time of about 5-100 seconds, as described with reference to FIG. 2A.

During re-supplying the first reaction gas, semiconductor atoms decomposed from the semiconductor source gas may be bonded and adsorbed to a surface of the etched second subsidiary layer 23a. In various embodiments, the re-supplying the first reaction gas may result in growth of a crystalline structure from the etched second subsidiary layer 23a, which may occur mainly in directions perpendicular and parallel to the top surface of the substrate 10. Accordingly, the maximum width in the specific direction (e.g., a direction substantially parallel to the x-axis illustrated in FIGS. 2A-2E) of the preliminary epitaxial layer 25 may be greater than the minimum width W1 in the same direction of the top surface of the active region 13. In other words, the preliminary epitaxial layer 25 may cover (e.g., overhang) at least portion of the recess region A, which may be formed near the interface between the active region 13 and the device isolation pattern 11.

In various embodiments, the first purging (Block 22) may be again performed (e.g., may be repeated) to purge the reaction chamber.

Referring to FIGS. 1 and 2F, the second reaction gas may be re-supplied into the reaction chamber (Block 23). Due to the presence of the etching gas in the second reaction gas (e.g., due to repeating Block 23), a portion of the preliminary epitaxial layer 25 may be etched to form the epitaxial layer 25a. For example, a side portion of the preliminary epitaxial layer 25 may be etched by the etching gas in the second reaction gas. The side portion of the preliminary epitaxial layer 25 may be a portion P protruding from the active region 13 toward the device isolation pattern 11. In various embodiments, as a result of the etching process, the maximum width W3 in the specific direction (e.g., a direction substantially parallel to the x-axis illustrated in FIGS. 2A-2F) of the epitaxial layer 25a may become substantially equal to the minimum width W1 in the same direction of the top surface of the active region 13. Furthermore, the recess region A, which may be formed near the interface between the active region 13 and the device isolation pattern 11, may be exposed by the epitaxial layer 25a.

In various embodiments, the epitaxial layer 25a may have a rounded portion, which may connect a side surface and a top surface thereof, and may have a curved sectional profile. A tangential plane of the rounded portion may form a first angle θ with respect to the top surface of the substrate 10. In various embodiments, the first angle θ may range from about 45 degrees to. about 65 degrees.

In various embodiments, the second purging (Block 24) may be again performed (e.g., may be repeated) to purge the reaction chamber.

After one or more iterations of the epitaxial process (Block 20), the substrate 10, in/on which the epitaxial layer 25a with a desired thickness is provided, may be unloaded from the reaction chamber (Block 30). For example, the substrate 10 provided with the epitaxial layer 25a may be unloaded to the load-lock chamber, via the transfer chamber, using the transfer robot provided in the transfer chamber.

According to various embodiments of methods of forming the epitaxial layer disclosed herein, supplying the first reaction gas including the semiconductor source gas (Block 21) and supplying the second reaction gas including the etching gas (Block 23) may be alternatingly and repeatedly performed to form an epitaxial layer with a desired thickness on the active region 13. In other words, by alternatingly and repeatedly growing a crystalline layer using the semiconductor source gas and alternatingly and repeatedly partially etching the grown crystalline layer using the etching gas, the epitaxial layer may be formed on the active region 13 to have a desired thickness. In a case in which the semiconductor source gas and the etching gas are simultaneously supplied to form the epitaxial layer, a crystalline layer may be grown in directions perpendicular and parallel to the top surface of the substrate 10, and the epitaxial layer may thus have a portion protruding from the active region 13 toward the device isolation pattern 11. The protruding portion of the epitaxial layer may cover at least upper portion of the recess region A, which may be formed near the interface between the active region 13 and the device isolation pattern 11. In such a case, a conductive material may be deposited in the recess region A during a subsequent deposition process, and the protruding portion of the epitaxial layer may serve as a factor making it difficult to remove the conductive materials from the recess region A. If the conductive material is not removed from the recess region A, the semiconductor device may suffer from deterioration in electric/electrical characteristics and reliability. By contrast, according to the methods of forming the epitaxial layer described herein, because the growing and etching processes are alternatingly and repeatedly performed, a horizontally grown portion of the epitaxial layer can be etched by the etching gas supplied in the etching process, such that the epitaxial layer can be formed to not cover/overhang the upper portion of the recess region A, which may be formed near the interface between the active region 13 and the device isolation pattern 11. As a result, the conductive materials to be deposited in a subsequent deposition process can be relatively easily removed from the recess region A, and this may provide a semiconductor device having improved electrical characteristics and reliability.

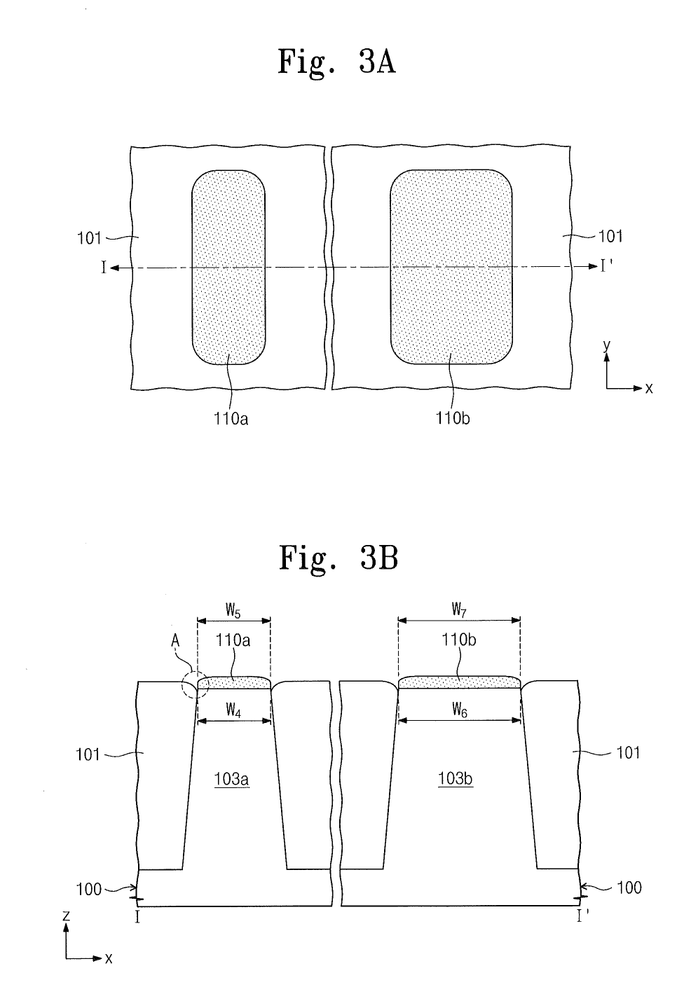

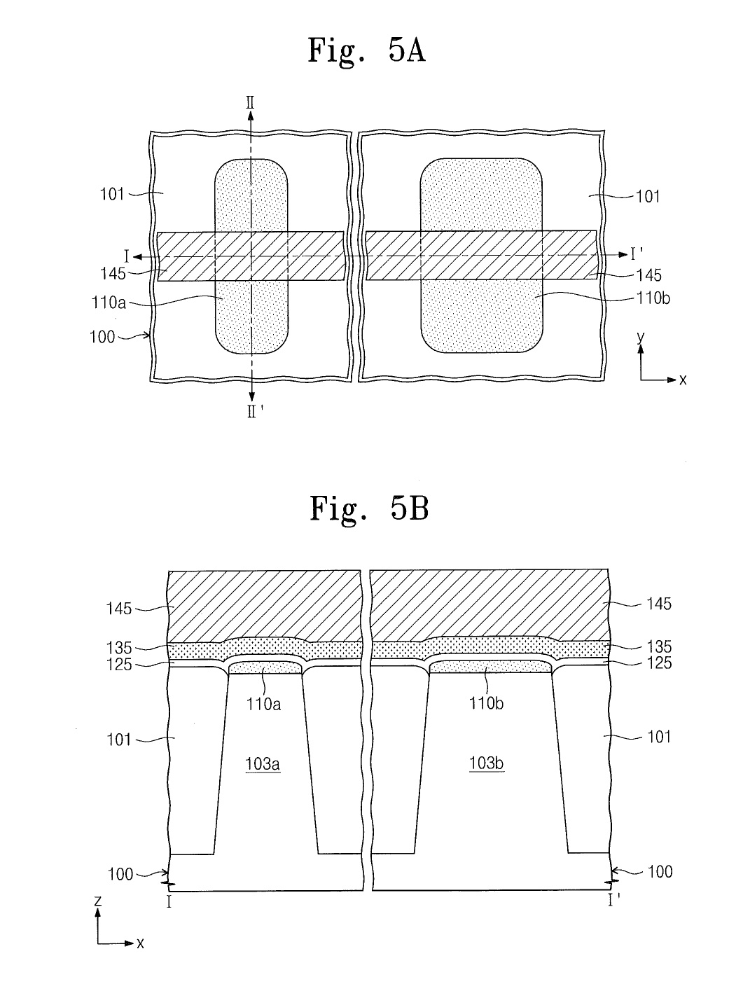

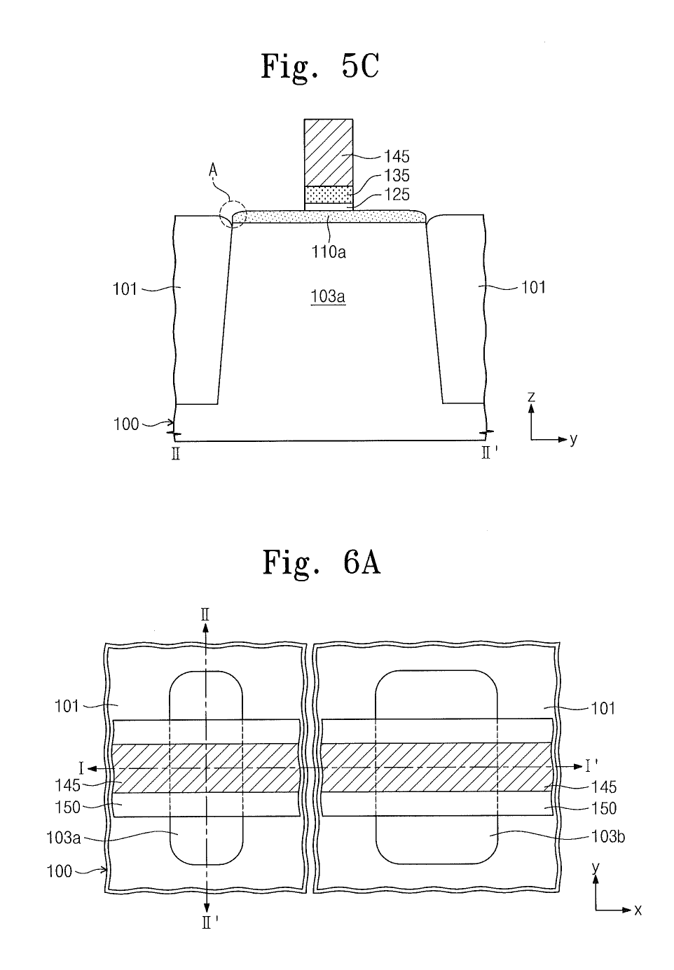

FIGS. 3A, 4A, 5A, 6A, 7A, and 8A are plan views illustrating a method of fabricating a semiconductor device according to various embodiments of the inventive concept, FIGS. 3B, 4B, 5B, 6B, 7B, and 8B are sectional views taken along a line I-II of FIGS. 3A, 4A, 5A, 6A, 7A, and 8A, respectively, and FIGS. 5C, 6C, 7C, and 8C are sectional views taken along a line II-II′ of FIGS. 5A, 6A, 7A, and 8A, respectively.

Referring to FIGS. 3A and 3B, a device isolation pattern 101 may be formed in/on a substrate 100 to define a first active region 103a and a second active region 103b. The formation of the device isolation pattern 101 may include forming a trench in the substrate 100 and filling the trench with an insulating material. In various embodiments, recess regions A may be formed near one or more interfaces between the first and second active regions 103a and 103b and the device isolation pattern 101.

The substrate 100 may include at least one of silicon or germanium. The first and second active regions 103a and 103b may be a portion of the substrate 100. In various embodiments, the area of a top surface of the first active region 103a may be smaller than the area of a top surface of the second active region 103b.

In various embodiments, before the formation of the device isolation pattern 101, a doping process may be further performed to dope the substrate 100 with dopants of a first conductivity type.

A first epitaxial layer 110a and a second epitaxial layer 110b may be formed on the first and second active regions 103a and 103b, respectively. The formation of the first and second epitaxial layers 110a and 110b may include growing a semiconductor layer using an epitaxial process, in which upper portions of the first and second active regions 103a and 103b are used as a seed layer. In various embodiments, the first and second epitaxial layers 110a and 110b may be formed using the epitaxial-layer-forming method described with reference to FIGS. 1 and 2A through 2F. In other words, the formation of the first and second epitaxial layers 110a and 110b may include supplying a first reaction gas containing a semiconductor source gas and supplying a second reaction gas containing an etching gas onto the substrate 100.

In various embodiments, the first and second epitaxial layers 110a and 110b may be formed in the same and identical process. For example, the first and second epitaxial layers 110a and 110b may be simultaneously formed in a single reaction chamber.

The maximum width W5 in a specific direction of the first epitaxial layer 110a may be substantially equal to the minimum width W4 in the same direction of the first active region 103a. Furthermore, the maximum width W7 in the specific direction of the second epitaxial layer 110b may be substantially equal to the minimum width W6 in the same direction of the second active region 103b. In various embodiments, the specific direction may be parallel to an x-axis (e.g., the x-axis in FIG. 3A).

In various embodiments, the first and second epitaxial layers 110a and 110b may include a semiconductor material whose energy band gap is less than that of a semiconductor material included in the first and second active regions 103a and 103b. For example, in a case in which the first and second active regions 103a and 103b comprise silicon, the first and second epitaxial layers 110a and 110b may include a silicon-germanium compound. The first epitaxial layer 110a and second epitaxial layer 110b may be formed to substantially entirely cover top surfaces of the first and second active regions 103a and 103b, respectively.

According to various embodiments of the inventive concept, it may be possible to reduce a difference in growth rate between the first epitaxial layer 110a and the second epitaxial layer 110b. For example, in a case in which the semiconductor source gas and the etching gas are simultaneously supplied to form the epitaxial layers, a difference in top surface area between the first and second active regions 103a and 103b may increase a difference in growth rate between the first and second epitaxial layers 110a and 110b. However, according to various embodiments of the inventive concept, the processes of supplying the first reaction gas containing the semiconductor source gas and supplying the second reaction gas containing the etching gas may be alternatingly and repeatedly performed to reduce the difference in growth rate between the first and second epitaxial layers 110a and 110b. In various embodiments, the first and second epitaxial layers 110a and 110b may be formed at substantially the same growth rate.

Accordingly, the first and second epitaxial layers 110a and 110b may be formed to have substantially the same thickness.

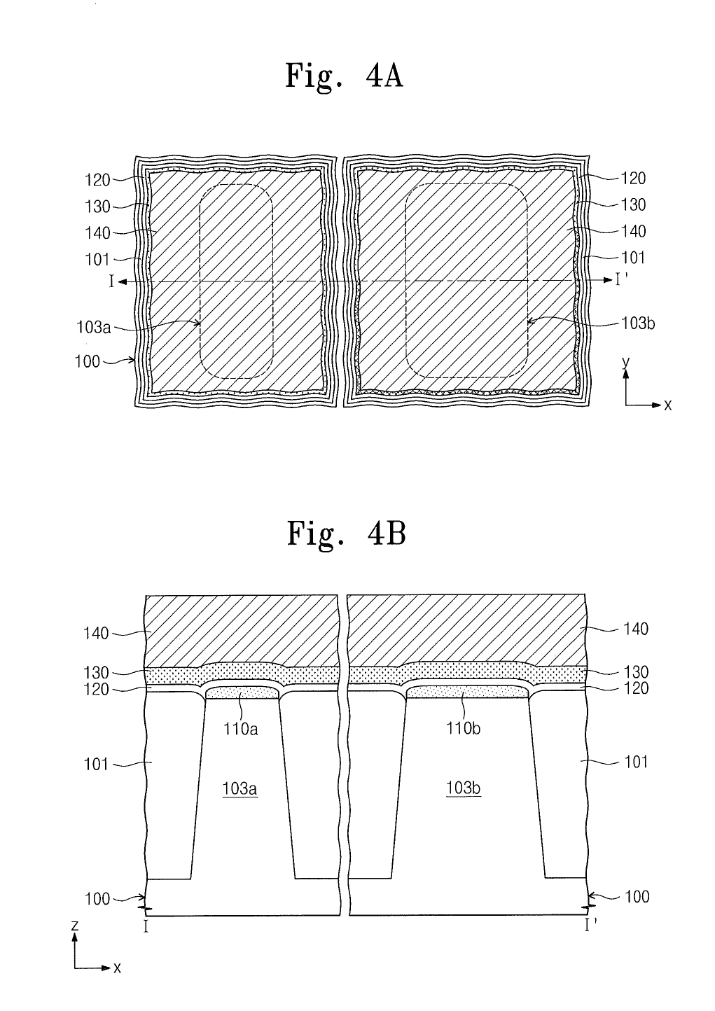

Referring to FIGS. 4A and 4B, after the formation of the first and second epitaxial layers 110a and 110b, a dielectric layer 120, a first conductive layer 130, and a second conductive layer 140 may be sequentially formed on the substrate 100. The dielectric layer. 120 may include a high-k dielectric layer. In various embodiments, the high-k dielectric layer may include a material having a dielectric constant greater than a silicon nitride layer. For example, the high-k dielectric layer may include at least one of insulating metal oxides, such as hafnium oxide, lanthanum oxide, or aluminum oxide.

The first conductive layer 130 may include a conductive metal nitride. For example, the first conductive layer 130 may include at least one of titanium nitride or tantalum nitride. The second conductive layer 140 may include a semiconductor material. For example, the second conductive layer 140 may include polycrystalline silicon.

Each of the dielectric layer 120, the first conductive layer 130, and the second conductive layer 140 may be formed using at least one of chemical vapor deposition (CVD), physical vapor deposition (PVD), or atomic layer deposition (ALD).

Alternatively, the dielectric layer 120 may be locally formed by a thermal oxidation process on top surfaces of the first and second active regions 103a and 103b.

Referring to FIGS. 5A through 5C, the second conductive layer 140, the first conductive layer 130, and the dielectric layer 120 may be sequentially patterned to form a dielectric pattern 125, a first conductive pattern 135, and a second conductive pattern 145.

The patterning process may include at least one anisotropic etching process. The patterning process may be performed to at least partially expose the first and second epitaxial layers 110a and 110b.

According to various embodiments of the inventive concept, as a result of the method described with reference to FIGS. 1 and 2A through 2F, the first and second epitaxial layers 110a and 110b may be formed to expose the recess regions A. This may enable effective removal of a conductive material, which may be deposited in the recess region A during the formation of the first and second conductive layers 130 and 140, in a subsequent etching process. As a result, it may be possible to reduce a process failure, which may otherwise be caused by the conductive material remaining in the recess region A.

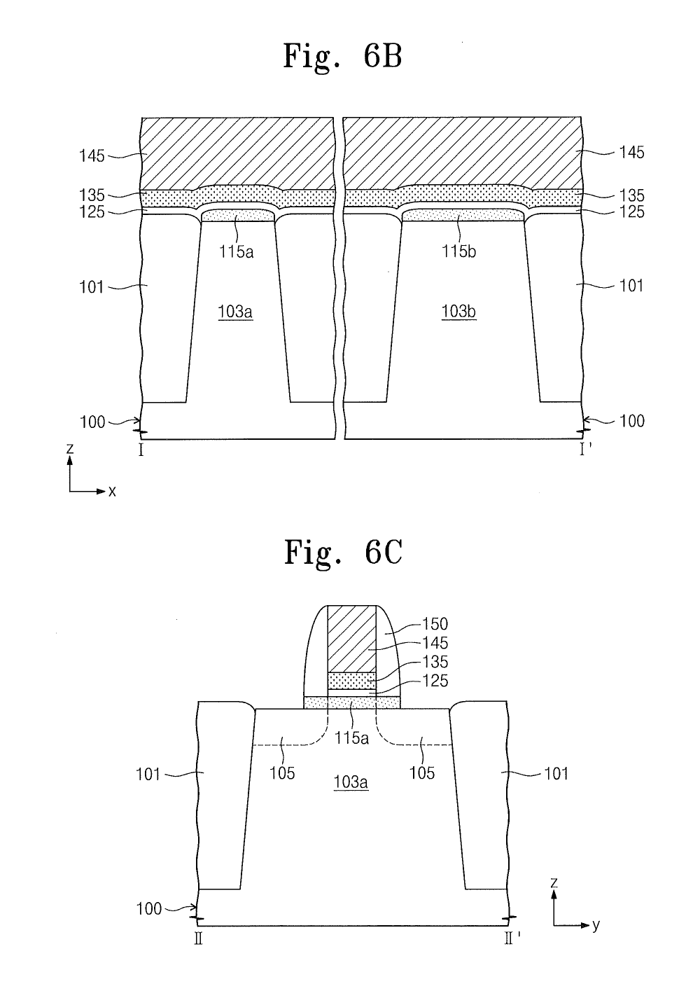

Referring to FIGS. 6A through 6C, a pair of doped regions 105 may be formed in each of the first and second active regions 103a and 103b, which may be positioned adjacent opposing sidewalls of the dielectric pattern 125. Each pair of doped regions 105 may be formed to have a specific depth from the top surface of the respective one of the first and second active regions 103a and 103b.

The formation of the doped regions 105 may include injecting dopants of a second conductivity type into the first and second active regions 103a and 103b. For example, one of the first and second conductivity types may be a p-type (e.g., with boron (B)), and the other may be an n-type (e.g., with phosphorus (P) or arsenic (As)). Accordingly, in various embodiments, the dopants of the first conductivity type may be p-type dopants (e.g., boron (B)), and the dopants of the second conductivity type may be n-type dopants (e.g., phosphorus (P) or arsenic (As)).

A pair of spacers 150 may be formed on the substrate 100 to cover opposing sidewalls of the second conductive pattern 145, the first conductive pattern 135, and the dielectric pattern 125. The formation of the spacers 150 may include conformally forming a spacer layer on the substrate 100 and then anisotropically etching the spacer layer to expose the first and second epitaxial layers. The spacer layer may be formed using at least one of chemical vapor deposition (CVD), physical vapor deposition (PVD), or atomic layer deposition (ALD).

In various embodiments, the first and second epitaxial layers 110a and 110b may be etched using the spacer layer and the second conductive pattern 145 as an etch mask. In various embodiments, the first and second active regions 103a and 103b may be exposed as a result of etching of first and second epitaxial layers 110a and 110b, such that a first epitaxial pattern 115a may be formed between the dielectric pattern 125 and the first active region 103a, and a second epitaxial pattern 115b may be formed between the dielectric pattern 125 and the second active region 103b.

In various embodiments, the first and second epitaxial patterns 115a and 115b may include portions doped with the same dopants as the doped regions 105.

In various embodiments, each of the first and second epitaxial patterns 115a and 115b may include a portion, which is positioned between a pair of the doped regions 105 in the first and second active regions 103a and 103b, respectively, to serve as a channel region of a transistor. In other words, the channel regions may be formed in the first and second epitaxial patterns 115a and 115b. The portions of the first and second epitaxial patterns 115a and 115b serving as the channel regions may be formed of a material having an energy band gap smaller than those of the first and second active regions 103a and 103b, and this may enable a decrease in the threshold voltage of transistors. Accordingly, it may be possible to realize a semiconductor device with improved electrical characteristics.

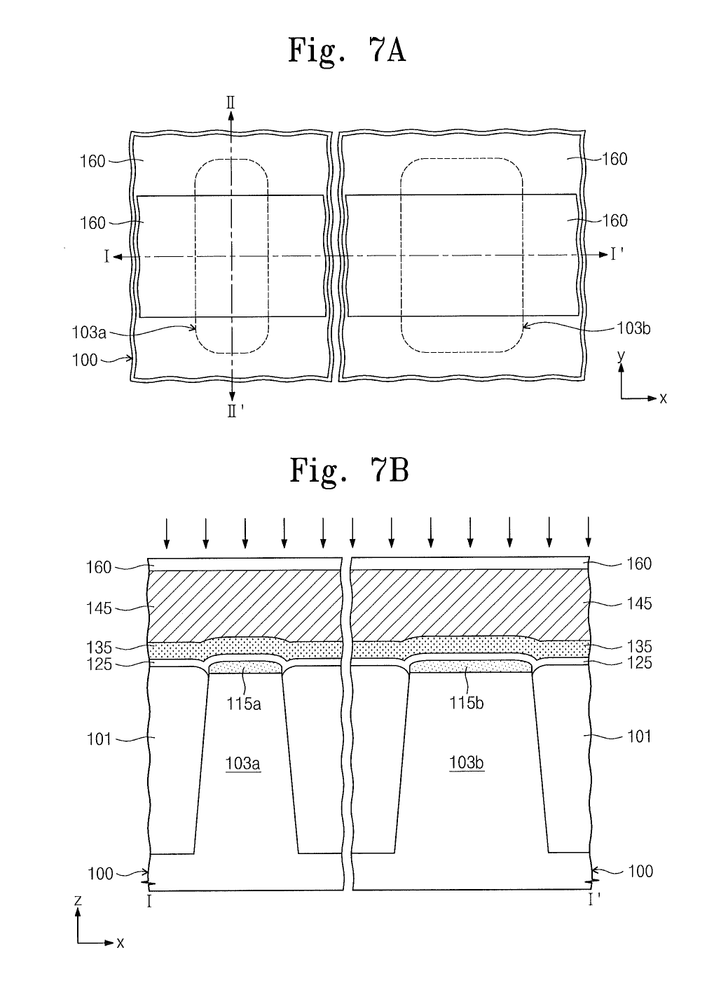

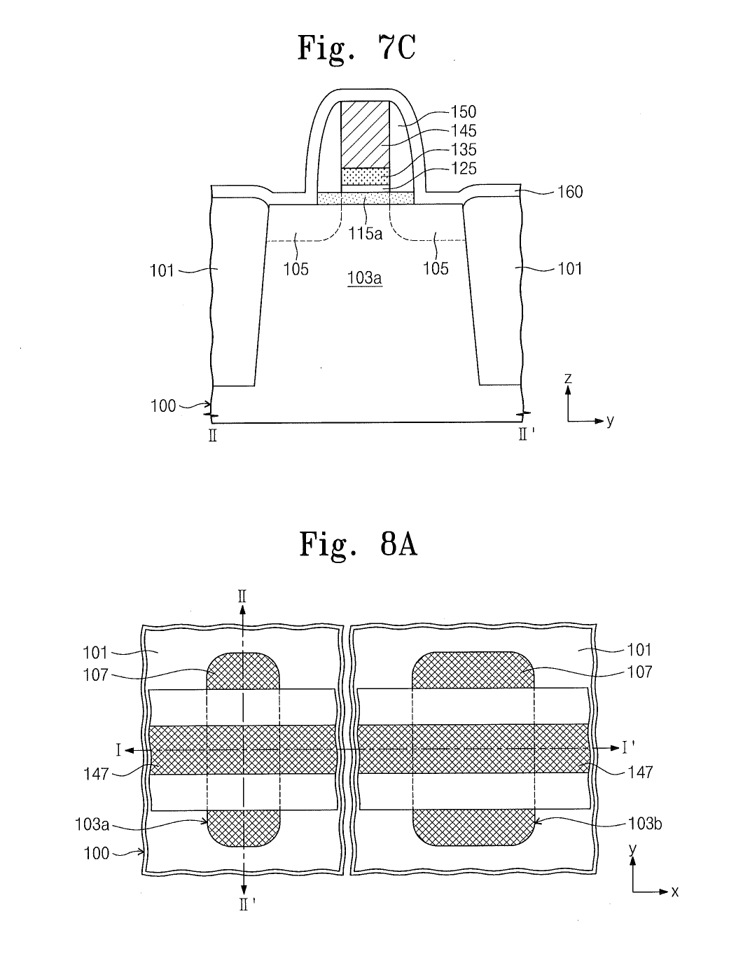

Referring to FIGS. 7A and 7B, a sacrificial metal layer 160 may be conformally formed on the substrate 100. The sacrificial metal layer 160 may include nickel or tungsten. The sacrificial metal layer 160 may be formed using at least one of chemical vapor deposition (CVD), physical vapor deposition (PVD), or atomic layer deposition (ALD).

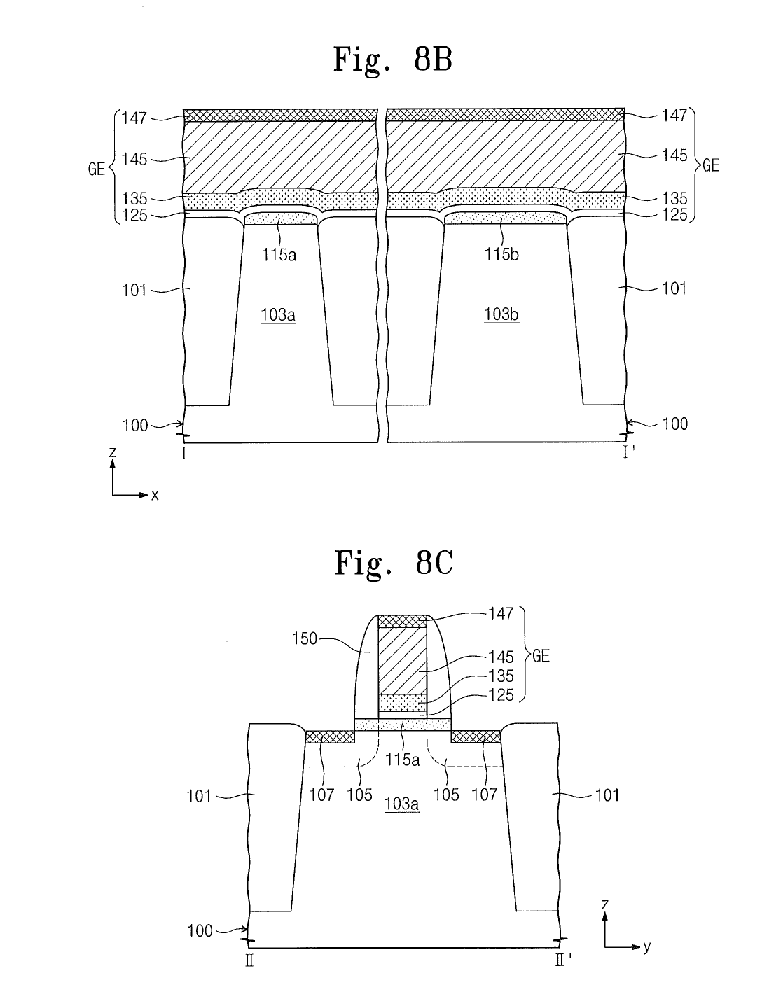

A thermal treatment process may be performed on the substrate 100 provided with the sacrificial metal layer 160. As a result of the thermal treatment process, a first metal-semiconductor compound pattern 147 and second metal-semiconductor compound pattern 107 may be formed, as shown in the FIGS. 8A and 8B.

During the thermal treatment process, metal elements in the sacrificial metal layer 160 may react with a semiconductor material in the second conductive pattern 145 to form the first metal-semiconductor compound pattern 147, and metal elements in the sacrificial metal layer 160 may be reacted with a semiconductor material in the first and second active regions 103a and 103b to form the second metal-semiconductor compound patterns 107. Accordingly, the first metal-semiconductor compound pattern 147 may be formed on the second conductive pattern 145, and the second metal-semiconductor compound pattern 107 may be formed on the doped regions 105 provided in the first and second active regions 103a and 103b.

In various embodiments, the dielectric pattern 125, the first conductive pattern 135, the second conductive pattern 145, and the first metal-semiconductor compound pattern 147 may constitute a gate electrode GE.

In a case in which the first active region 103a, the second active region 103b, and the second conductive pattern 145 include the same semiconductor material, the first and second metal-semiconductor compound patterns 147 and 107 may be formed to include the same metal-semiconductor compound. For example, in a case in which the first and second active regions 103a and 103b include silicon and the second conductive pattern 145 includes polycrystalline silicon, the first and second metal-semiconductor compound patterns 147 and 107 may be formed to include a metal silicide layer.

The sacrificial metal layer 160 may be removed after the formation of the first and second metal-semiconductor compound patterns 147 and 107. The removal of the sacrificial metal layer 160 may be performed using a wet etching process.

A semiconductor device according to various embodiments of the inventive concept may include an epitaxial layer, which may be formed by alternatingly and repeatedly supplying the first reaction gas including the semiconductor source gas and the second reaction gas including the etching gas. In other words, the crystal growing process using the semiconductor source gas and the etching process using the etching gas to partially etch the grown layer may be alternatingly and repeatedly performed to form the epitaxial layer with a desired thickness on the active regions. In a case in which the semiconductor source gas and the etching gas are simultaneously supplied to form the epitaxial layer, a crystalline layer may be grown in directions perpendicular and parallel to the top surface of the substrate, and the epitaxial layer may thus have a portion protruding from the active region toward the device isolation pattern. The protruding portion of the epitaxial layer may cover at least an upper portion of the recess region, which may be formed near the interface between the active region and the device isolation pattern. In such a case, a conductive material may be deposited in the recess region during a subsequent deposition process, and the protruding portion of the epitaxial layer may make it difficult to remove the conductive material from the recess region. If the conductive material is not removed from the recess region, the semiconductor device may suffer from deterioration in electrical characteristics and reliability. In contrast, according to various embodiments of the inventive concept, however, because the growing and etching processes are alternatingly and repeatedly performed, a horizontally-grown portion of the epitaxial layer can be etched by the etching gas supplied in the etching process, such that the epitaxial layer can be formed to not cover/overhang an upper portion of the recess region. As a result, conductive materials to be deposited in a subsequent deposition process can be relatively easily removed from the recess region, and a semiconductor device having improved electrical characteristics and reliability may thus be provided.

Furthermore, for the semiconductor device according to various embodiments of the inventive concept, the epitaxial layers may include a semiconductor material, whose energy band gap is lower than that of a semiconductor material of the active regions, and the channel region of transistors may be formed in the epitaxial layers. This may enable a decrease in a threshold voltage of transistors. Accordingly, it may be possible to realize a semiconductor device with improved electrical characteristics.

FIG. 8A is a plan view illustrating a semiconductor device according to various embodiments of the inventive concept. FIGS. 8B and 8C are sectional views taken along lines I-I′ and II-II′, respectively, of FIG. 8A. For the sake of brevity, the elements and features of this example that are similar to those previously shown and described may not be described in much further detail.

Referring to FIGS. 8A through 8C, the device isolation pattern 101 may be provided in the substrate 100 to define the first active region 103a and the second active region 103b. In various embodiments, the first and second active regions 103a and 103b may be portions of the substrate 100 that are doped with dopants of the first conductivity type.

The gate electrode GE may be provided on the substrate 100 to extend along a first direction (e.g., along a direction parallel to the x-axis) and cross the first and second active regions 103a and 103b. The gate electrode GE may include the dielectric pattern 125, the first conductive pattern 135, the second conductive pattern 145, and the first metal-semiconductor-compound pattern 147.

The dielectric pattern 125 may include a high-k material. For example, the high-k material may include at least one of metal oxides (e.g., hafnium oxide or aluminum oxide), metal-semiconductor-oxygen compounds (e.g., a hafnium-silicon-oxygen compound), or metal-semiconductor-oxygen-nitrogen compounds (e.g., a hafnium-silicon-oxygen-nitrogen compound). Alternatively, the dielectric pattern 125 may include a dielectric material such as silicon oxide, silicon nitride, or silicon oxynitride.

In various embodiments, the top surface of the dielectric pattern 125 may be substantially wholly overlapped by the first conductive pattern 135. Accordingly, the top/uppermost surface of the dielectric pattern 125 may be positioned at a level equal to or lower than the lowermost surface of the first conductive pattern 135.

In various embodiments, the dielectric pattern 125 may include a pair of sidewalls aligned to opposing sidewalls of the first conductive pattern 135. Alternatively, the dielectric pattern 125 may extend to substantially wholly cover the substrate 100. For example, the dielectric pattern 125 may extend laterally beyond opposing sidewalls of the first conductive pattern 135.

The first conductive pattern 135 may include a conductive metal nitride. The second conductive pattern 145 may include a semiconductor material. For example, the second conductive pattern 145 may include a polycrystalline silicon layer.

A pair of the doped regions 105 may be provided in each of the first and second active regions 103a and 103b, which may be positioned adjacent opposing sidewalls of the gate electrode GE. The doped regions 105 may be formed to have a specific depth from the top surface of the active regions 103a and 103b. The doped regions 105 may be portions of the substrate 100 that are doped with dopants of the second conductivity type. In various embodiments, the second conductivity type may be opposite to the first conductivity type.

The spacers 150 may be formed on the substrate 100 to cover opposing sidewalls of the gate electrode GE. The spacers 150 may include a dielectric material.

The first epitaxial pattern 115a may be disposed between the first active region 103a and the gate electrode GE, and the second epitaxial pattern 115b may be disposed between the second active region 103b and the gate electrode GE.

The maximum width in the first direction (e.g., a direction parallel to the x-axis) of the first epitaxial pattern 115a may be substantially equal to the minimum width in the first direction of the first active region 103a. Furthermore, the maximum width in the first direction of the second epitaxial pattern 115b may be substantially equal to the minimum width in the same direction of the second active region 103b. For example, the first and second epitaxial patterns 115a and 115b may expose recess regions A, which may be formed at interfaces between the first and second active regions 103a and 103b and the device isolation pattern 101. Accordingly, it may be possible to reduce a process failure, which may be caused by the conductive material to be deposited in the recess region.

In various embodiments, each of the first and second epitaxial patterns 115a and 115b may include a rounded portion connecting a side surface thereof with a top surface thereof. A tangential plane of the rounded portion may form an angle with respect to the top surface of the substrate 100. In various embodiments, the angle may range from about 45 degrees to about 65 degrees.

In various embodiments, the first and second epitaxial patterns 115a and 115b may extend along a second direction beyond opposing sidewalls of the gate electrode GE. From the plan view, the second direction may be parallel to the y-axis and/or may be perpendicular to the first direction.

In various embodiments, the first and second epitaxial patterns 115a and 115b may have substantially the same thickness.

Extended portions of the first and second epitaxial patterns 115a and 115b may be disposed between the spacers 150 and the first and second active regions 103a and 103b. In various embodiments, the extended portions may be doped with the same dopants as the doped regions 105.

In various embodiments, the first and second epitaxial patterns 115a and 115b may include a semiconductor material whose energy band gap is less than that of a semiconductor material included in the first and second active regions 103a and 103b. For example, in a case in which the first and second active regions 103a and 103b are formed of silicon, the first and second epitaxial patterns 115a and 115b may include a germanium layer. In particular, the first and second epitaxial patterns 115a and 115b may include at least one of silicon-germanium or germanium.

Channel regions may be formed in portions of the first and second epitaxial patterns 115a and 115b, which are positioned between the doped regions 105. Because the channel regions are formed in the first and second epitaxial patterns 115a and 115b having an energy band gap smaller than that of the first and second active regions 103a and 103b, it may be possible to realize a transistor having a decreased threshold voltage. Accordingly, the electrical characteristics and reliability of a semiconductor device may be improved.

The second metal-semiconductor compound pattern 107 may be provided in upper regions of the doped regions 105. The second metal-semiconductor compound pattern 107 may include a semiconductor material of the first and second active regions 103a and 103b. For example, in a case in which the first and second active regions 103a and 103b include silicon, the second metal-semiconductor compound pattern 107 may include metal silicide.

The afore-described semiconductor device may be configured to have the same/similar technical effects as those in the semiconductor device fabricating methods described with reference to FIGS. 3A through 8A.

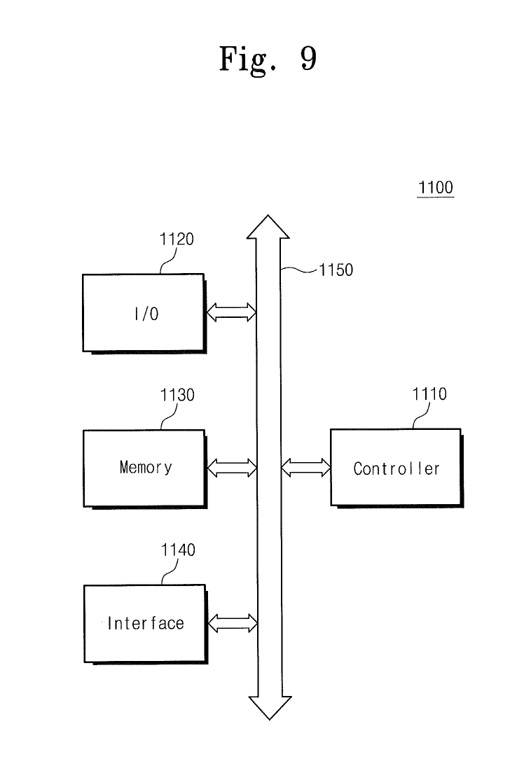

FIG. 9 is a schematic block diagram illustrating an example of a memory system including a semiconductor device, according to various embodiments of the inventive concept.

Referring to FIG. 9, an electronic system 1100 according to various embodiments may include a controller 1110, an input/output (110) unit 1120, a memory unit/device 1130, an interface unit 1140, and a bus 1150. At least two of the controller 1110, the I/O unit 1120, the memory unit/device 1130, and the interface unit 1140 may communicate with each other through the bus 1150. The bus 1150 may correspond to a path through which electrical signals are transmitted.

The controller 1110 may include at least one of a microprocessor, a digital signal processor, a microcontroller, or another logic device. The other logic device may have a similar function to any one of the microprocessor, the digital signal processor, and the microcontroller. The I/O unit 1120 may include a keypad, a keyboard, and/or a display unit. The memory unit/device 1130 may store data and/or commands. The memory unit/device 1130 may include at least one of the semiconductor memory devices described herein. Additionally or alternatively, the memory unit/device 1130 may include another type of semiconductor memory device. For example, the memory unit/device 1130 may further include a nonvolatile memory device, a magnetic memory device, a phase change memory device, a dynamic random access memory (DRAM) device, and/or a static RAM (SRAM) device. The interface unit 1140 may transmit electrical data to a communication network and/or may receive electrical data from a communication network. The interface unit 1140 may operate wirelessly or by cable. For example, the interface unit 1140 may include an antenna for wireless communications and/or a transceiver for cable communication. The electronic system 1100 may further include a fast SRAM device that acts as a cache memory for improving an operation of the controller 1110.

The electronic system 1100 may be applied to (e.g., included in) a personal digital assistant (PDA), a portable computer, a web tablet, a wireless phone, a mobile phone, a digital music player, a memory card, or an electronic product. The electronic product may receive and/or transmit information data wirelessly.

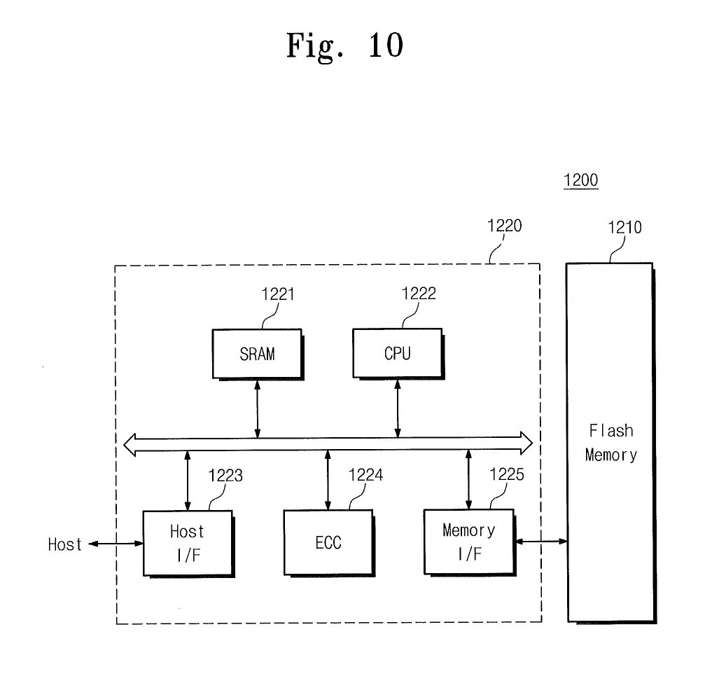

FIG. 10 is a schematic block diagram illustrating an example of a memory card including a semiconductor device according to various embodiments of the inventive concept.

Referring to FIG. 10, a memory card 1200 according to various embodiments of the inventive concept may include a memory device 1210. The memory device 1210 may include at least one of the semiconductor devices described herein. Alternatively, the memory device 1210 may further include another type of semiconductor memory device. For example, the memory device 1210 may further include a nonvolatile memory device, a dynamic random access memory (DRAM) device, and/or a static RAM (SRAM) device, which may be realized on the basis of various embodiments of the inventive concept. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. In various embodiments, the SRAM device 1221 may also be a semiconductor device to be realized on the basis of various embodiments of the inventive concept. Moreover, the memory controller 1220 may further include a host interface (I/F) unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data that are read out from the memory device 1210. The memory card 1200 may further include a read only memory (ROM) device that stores code data to interface with the host. The memory card 1200 may be used as a portable data storage card. Alternatively, the memory card 1200 may replace hard disks of computer systems as solid state disks (SSD) of the computer systems.

The semiconductor devices described herein may be encapsulated using various and diverse packaging techniques. For example, the semiconductor devices according to various embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique, and a wafer-level processed stack package (WSP) technique.

The package in which the semiconductor device according to various embodiments is mounted may further include at least one semiconductor device (e.g., a controller and/or a logic device) that controls the semiconductor device.

According to various embodiments of the inventive concepts, a semiconductor device may include an epitaxial layer, which may be formed by alternatingly and repeatedly performing processes of growing and etching a crystalline layer. The epitaxial layer may be formed to expose a recess region, which may be formed near an interface between an active region and a device isolation pattern, and it may therefore be possible to relatively easily remove conductive materials, which will be deposited in a subsequent process, from the recess region. Accordingly, it may be possible to reduce occurrence of a failure that may be caused by the conductive material in the recess region.

In addition, according to various embodiments of the inventive concepts, channel regions of transistors may be formed in the epitaxial layer applied with an electric voltage. This may enable a reduced threshold voltage of the transistors and may provide a semiconductor device with improved reliability and electrical characteristics.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

1. A method of forming a semiconductor device, comprising:
forming a device isolation pattern in a substrate to define an active region;
forming an epitaxial layer on the active region; and
forming a gate electrode on the epitaxial layer to cross the active region,
wherein forming the epitaxial layer comprises:
growing a crystalline layer using a semiconductor source gas in a reaction chamber;
performing a first purging of the reaction chamber;
etching the crystalline layer using an etching gas in the reaction chamber; and
performing a second purging of the reaction chamber.

2. The method of claim 1, wherein a cyclic process, including each of growing the crystalline layer using the semiconductor, source gas, performing the first purging, etching the crystalline layer using the etching gas, and performing the second purging, is performed two or more times during the forming of the epitaxial layer.

3. The method of claim 1, wherein:
growing the crystalline layer using the semiconductor source gas is performed to grow the crystalline layer in vertical and horizontal directions with respect to a top surface of the substrate; and
etching the crystalline layer is performed to etch the horizontally grown portion of the crystalline layer.

4. The method of claim 1, wherein etching the crystalline layer is performed using a reaction gas including the etching gas and not including a semiconductor source gas.

5. The method of claim 4, wherein the etching gas includes halogen elements.

6. The method of claim 1, wherein forming the gate electrode comprises:
forming a dielectric layer, a first conductive layer, and a second conductive layer on the substrate in a sequential manner; and
patterning the dielectric layer, the first conductive layer, and the second conductive layer,
wherein the first conductive layer comprises a conductive metal nitride layer and the dielectric layer comprises a high-k dielectric layer.

7. The method of claim 6, wherein forming the gate electrode further comprises:
forming a sacrificial metal layer on the substrate; and
performing a thermal treatment process on the substrate to form a first metal-semiconductor compound pattern on the patterned second conductive layer.

8. The method of claim 7, wherein forming the sacrificial metal layer and performing the thermal treatment process comprise forming a second metal-semiconductor compound pattern on the active region.

9. The method of claim 1, further comprising forming spacers on the active region to cover opposing sidewalls of the gate electrode,
wherein forming the spacers comprises:
forming a spacer layer on the substrate; and
anisotropically etching the spacer layer to expose the epitaxial layer.

10. The method of claim 9, further comprising etching the epitaxial layer using the gate electrode and the spacers as an etch mask to expose the active region.

11. The method of claim 1, wherein:
forming the device isolation pattern to define the active region comprises defining a first active region and a second active region;
forming the epitaxial layer comprises forming a first epitaxial layer and a second epitaxial layer;
the first epitaxial layer is between the first active region and the gate electrode, and the second epitaxial layer is between the second active region and the gate electrode;
a top surface of the first active region has a greater area than an top surface of the second active region; and
a growth rate of the first epitaxial layer is substantially equal to that of the second epitaxial layer.

12. The method of claim 1, wherein:
forming the epitaxial layer is performed at a temperature ranging from about 300 degrees Celsius to about 900 degrees Celsius; and
each of etching the crystalline layer using the etching gas and growing crystalline layer using the semiconductor source gas is performed during a process time ranging from about 5 seconds to about 100 seconds.

13-15. (canceled)

16. A method of forming a semiconductor device, comprising:
supplying a semiconductor source gas to a substrate in an epitaxy reaction chamber to grow a crystalline structure on the substrate;
supplying an etching gas in the epitaxy reaction chamber to etch a portion of the crystalline structure;
repeatedly supplying the semiconductor source gas to grow the crystalline structure and supplying the etching gas to etch the crystalline structure to form an epitaxial layer that is on an active region of the substrate and that exposes a recess between the active region of the substrate and an adjacent device isolation pattern;
forming a dielectric layer on the epitaxial layer;
forming first and second conductive layers on the dielectric layer; and
patterning the dielectric layer and the first and second conductive layers to expose the recess.

17. The method of claim 16, further comprising:
purging the epitaxy reaction chamber a first time between supplying the semiconductor source gas to grow the crystalline structure and supplying the etching gas to etch the crystalline structure; and
purging the epitaxy reaction chamber a second time after supplying the etching gas to etch the crystalline structure.

18. The method of claim 16, wherein:
forming the epitaxial layer on the active region of the substrate comprises forming first and second active regions on the substrate;
forming the epitaxial layer comprises forming a first epitaxial layer and a second epitaxial layer;
the first epitaxial layer is between the first active region and the dielectric layer, and the second epitaxial layer is between the second active region and the dielectric layer;
a top surface of the first active region has a greater area than a top surface of the second active region; and
a thickness of the first epitaxial layer is substantially equal to a thickness of the second epitaxial layer.

19. The method of claim 18, further comprising:
forming spacers on opposing sidewalls of the dielectric layer and on opposing sidewalls of the first and second conductive layers; and
etching the first and second epitaxial layers using the spacers and the second conductive layer as an etch mask.

20. The method of claim 18, further comprising:
forming channel regions in the first and second epitaxial layers, wherein each of the first and second epitaxial layers includes a semiconductor material including an energy band gap that is less than an energy band gap of a semiconductor material in the first and second active regions, respectively.
